(19) United States
(12) Patent Application Publication
(10) Pub. No.: US 2006/0068588 A1
(43) Pub. Date: Mar. 30, 2006

(54) Low-pressure deposition of ruthenium and rhenium metal layers from metal carbonyl precursors

(75) Inventors: Hideaki Yamasaki, Kofu-City (JP); Kenji Suzuki, Guilderland, NY (US); Emmanuel Guidotti, Fishkill, NY (US); Enrico Mosca, Ossining, NY (US); Gert Leusink, Saltpoint, NY (US); Yumiko Kawano, Kofu-city (JP); Fenton R. McFeely, Ossining, NY (US); Sandra G. Malhotra, Beacon, NY (US)

Correspondence Address: PILLSBURY WINTHROP SHAW PITTMAN, LLP, P.O. BOX 10500, MCLEAN, VA, 22102, US

(73) Assignees: Tokyo Electron Limited, Tokyo (JP); International Business Machines Corporation, Armonk, NY (US)

(21) Appl. No.: 10/953,466

(22) Filed: Sep. 30, 2004

(51) Int. Cl. H01L 21/44

(52) U.S. Cl. 438/681; 438/686

(57) ABSTRACT

A method for depositing Ru and Re metal layers on substrates with high deposition rates, low particulate contamination, and good step coverage on patterned substrates is presented. The method includes providing a substrate in a process chamber, introducing a process gas in the process chamber in which the process gas comprises a carrier gas and a metal precursor selected from the group consisting of a ruthenium-carbonyl precursor and a rhenium-carbonyl precursor. The method further includes depositing a Ru or Re metal layer on the substrate by a thermal chemical vapor deposition process at a process chamber pressure less than about 20 mTorr.

### FIELD OF THE INVENTION

The present invention relates to semiconductor processing, and more particularly, to a method for depositing thin ruthenium and rhenium metal layers in a low-pressure thermal chemical vapor deposition process.

### BACKGROUND OF THE INVENTION

The introduction of copper (Cu) metal into multilayer metallization schemes for manufacturing integrated circuits (ICs), can necessitate the use of diffusion barriers/liners to promote adhesion and growth of the Cu layers, and to prevent diffusion of Cu into the dielectric materials. Barriers/liners that are deposited onto dielectric materials can include refractive materials such as ruthenium (Ru), rhenium (Re), tungsten (W), molybdenum (Mo), and tantalum (Ta), that are non-reactive and immiscible with Cu and can offer low electrical resistivity. Current integration schemes that integrate Cu metallization and dielectric materials can require barrier/liner deposition processes at substrate temperatures between about 400° C. and about 500° C., or lower.

Thermal chemical vapor deposition (TCVD) is a particularly attractive method for forming thin layers on substrates in the semiconductor industry, because the method has the ability to readily control the composition of the thin layers and to form a thin layer without contamination of, or damage to, the substrate. TCVD can also be used to deposit the desired thin layer into holes, trenches, and other stepped structures. In situations where conformal thin layer deposition is required, TCVD can be a preferred method of deposition, since evaporation and sputtering techniques cannot be used to form a conformal thin layer.

TCVD processes require suitable precursors that are sufficiently volatile to permit a rapid transport of their vapors into the TCVD process chamber to deposit layers at sufficiently high deposition rates for device manufacturing. The precursors should be relatively stable and decompose cleanly on the substrate in the process chamber to deposit a high-purity layer at the desired substrate temperature.

### SUMMARY OF THE INVENTION

Embodiments of the present invention, as broadly described herein, provide for a method of depositing thin Ru and Re metal layers on a substrate in a thermal chemical vapor deposition process. The method utilizes ruthenium-carbonyl and rhenium-carbonyl precursors that can provide high deposition rates of Ru and Re metal layers on a substrate, low particulate contamination, and good step coverage on patterned substrates.

In one embodiment of the invention, the method comprises providing a substrate in a process chamber, introducing a process gas in the process chamber in which the process gas comprises a carrier gas and a metal-carbonyl precursor selected from the group consisting of a ruthenium-carbonyl precursor and a rhenium-carbonyl precursor. The method also comprises depositing a Ru or Re metal layer on the substrate by a thermal chemical vapor deposition process at a process chamber pressure less than about 20 mTorr. Alternately, the process chamber pressure can be less than about 10 mTorr. In one embodiment of the invention, the ruthenium-carbonyl precursor can contain Ru₃(CO)₁₂ and the rhenium-carbonyl precursor can contain Re₂(CO)₁₀.

In another embodiment of the invention, the method comprises providing a patterned substrate in a process chamber, the patterned substrate containing one or more vias, trenches or combinations thereof, introducing a process gas in the process chamber, the process gas comprising a carrier gas and a metal-carbonyl precursor selected from the group consisting of a ruthenium-carbonyl precursor and a rhenium-carbonyl precursor, and depositing a Ru or Re metal layer on the patterned substrate by a thermal chemical vapor deposition process, wherein the process gas pressure in the process chamber is less than about 20 mTorr. Alternately, the process chamber pressure can be less than about 10 mTorr.

Other aspects of the invention will be made apparent from the description that follows and from the drawings appended hereto.

### BRIEF DESCRIPTION OF THE DRAWINGS

Embodiments of the present invention will be described, by way of example, with reference to the accompanying drawings in which:

FIG. 1 is a simplified block-diagram illustrating a processing system for depositing Ru and Re metal layers on a substrate, according to an embodiment of the invention;

FIGS. 2A-2C schematically depict substrates containing thin Ru or Re metal layers deposited thereon, according to embodiments of the invention;

FIG. 3 shows a flowchart for depositing a metal layer, according to an embodiment of the invention; and

FIG. 4 shows a cross-sectional SEM micrograph of a Ru layer deposited by a low-pressure thermal chemical vapor deposition process according to an embodiment of the invention.

### DETAILED DESCRIPTION OF SEVERAL EMBODIMENTS

Various embodiments of the present invention are discussed below. When appropriate, like reference numerals are used to refer to like features. The embodiments presented herein are intended to be merely exemplary of the wide variety of embodiments contemplated within the scope of the present invention, as would be appreciated by those skilled in the art. Accordingly, the present invention is not limited solely to the embodiments presented but also encompasses any and all variations that would be appreciated by those skilled in the art.

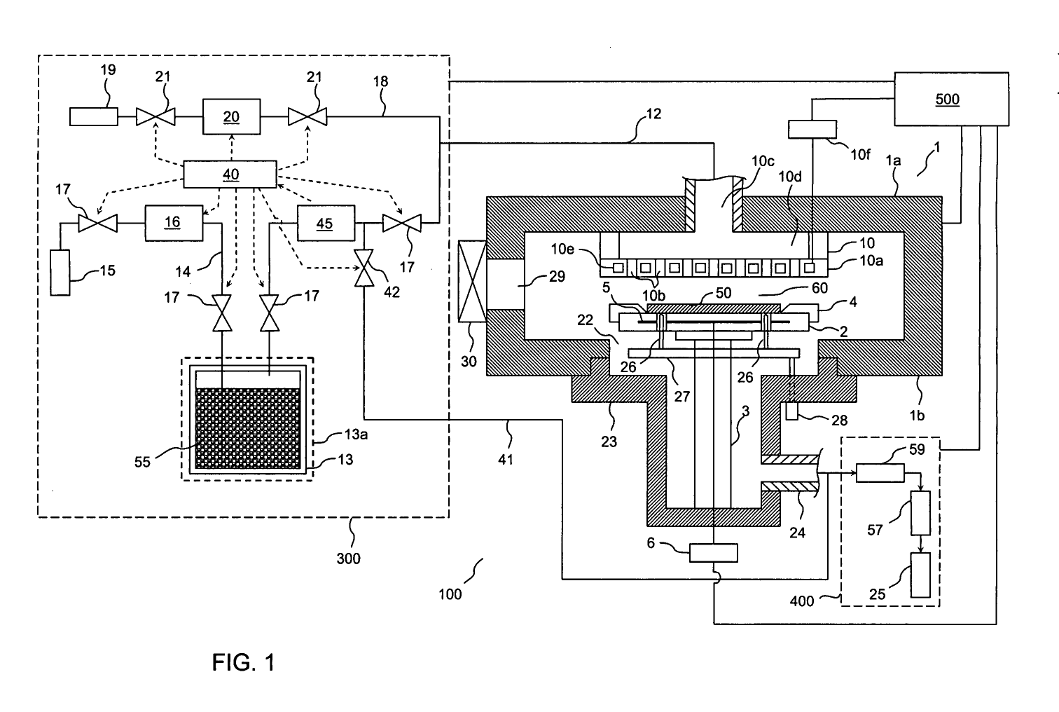

FIG. 1 is a simplified block-diagram of a processing system for depositing Ru and Re metal layers on a substrate according to an embodiment of the invention. The processing system 100 comprises a process chamber 1 that includes an upper chamber section 1a, a lower chamber section 1b, and an exhaust chamber 23. A circular opening 22 is formed in the middle of the lower chamber section 1b, where the bottom section 1b connects to the exhaust chamber 23.

Provided inside the process chamber 1 is a substrate holder 2 for horizontally holding a substrate (wafer) 50 to be processed. The substrate holder 2 is supported by a cylindrical support member 3, which extends upward from the center of the lower part of the exhaust chamber 23. A guide ring 4 for positioning the substrate 50 on the substrate holder 2 is provided on the edge of the substrate holder 2. Furthermore, the substrate holder 2 contains a heater 5 that is controlled by power source 6, and is used for heating the substrate 50. The heater 5 may comprise a resistive heater or any heater suitable for such purposes, such as, for example, a lamp heater.

During processing, the heated substrate 50 can thermally decompose a metal-carbonyl precursor 55 and enable deposition of a metal layer on the substrate 50. According to one embodiment of the present invention, the metal-carbonyl precursor 55 may comprise a ruthenium-carbonyl precursor, such as, for example, Ru₃(CO)₁₂. Alternatively, in accordance with another embodiment of the invention, the metal-carbonyl precursor 55 may comprise a rhenium-carbonyl precursor, such as, for example, Re₂(CO)₁₀. With this said, it will be appreciated by those skilled in the art that other ruthenium-carbonyl precursors and rhenium-carbonyl precursors can be used without departing from the scope of the present invention.

The substrate holder 2 is heated to a pre-determined temperature that is suitable for depositing the desired Ru or Re metal layer onto the substrate 50. A heater (not shown) is embedded in the walls of the process chamber 1 to heat the chamber walls to a pre-determined temperature. The heater can maintain the temperature of the walls of process chamber 1 from about 40° C. to about 80° C. A pressure gauge (not shown) is used to measure the process chamber pressure.

As shown in FIG. 1, the upper chamber section 1a of process chamber 1 includes a showerhead 10 with a showerhead plate 10a disposed at the bottom of the showerhead 10. The showerhead plate 10a contains multiple gas delivery holes 10b for delivering a process gas comprising the metal-carbonyl precursor 55 into a processing zone 60 located above the substrate 50.

The upper chamber section 1b includes an opening 10c for introducing a process gas from a gas line 12 into a gas distribution compartment 10d. To prevent the decomposition of the metal-carbonyl precursor 55 inside the showerhead 10, concentric coolant flow channels 10e are provided to control the temperature of the showerhead 10. A coolant fluid, such as, for example, water, can be supplied to the coolant flow channels 10e from a coolant fluid source 10f in order to control the temperature of showerhead 10 from about 20° C. to about 100° C.

A precursor delivery system 300 is coupled to the process chamber 1 via the gas line 12. The precursor delivery system 300 comprises, inter alia, a precursor container 13, a precursor heater 13a, a gas source 15, mass flow controllers (MFCs) 16 and 20, a gas flow sensor 45, and a gas controller 40. The precursor container 13 contains a solid metal-carbonyl precursor 55, and the precursor heater 13a is provided to heat the precursor container 13 and maintain the metal-carbonyl precursor 55 at a temperature that produces a desired vapor pressure of the metal-carbonyl precursor 55.

The metal-carbonyl precursor 55 can be delivered to the process chamber 1 using a carrier gas to enhance the delivery of the precursor 55 to the process chamber 1. A gas line 14 provides a carrier gas from the gas source 15 to the precursor container 13 and the mass flow controller (MFC) 16 can be used to control the carrier gas flow. The carrier gas may be introduced into the lower part of precursor container 13 so as to percolate through the solid metal-carbonyl precursor 55. Alternately, the carrier gas may be introduced into the precursor source 13 and distributed across the top of the solid metal-carbonyl precursor 55.

The sensor 45 is configured to measure the total gas flow from the precursor container 13. The sensor 45 can, for example, comprise a MFC and the amount of metal-carbonyl precursor 55 delivered to the process chamber 1 can be determined using the sensor 45 and the mass flow controller 16. Alternately, the sensor 45 can comprise a light absorption sensor to measure the concentration of the metal-carbonyl precursor 55 in the gas flow to the process chamber 1.

A bypass line 41 is located downstream from the sensor 45 and connects the gas line 12 to the exhaust line 24. The bypass line 41 is provided for evacuating the gas line 12 and for stabilizing the supply of the metal-carbonyl precursor 55 to the process chamber 1. In addition, a valve 42, located downstream from the branching of the gas line 12, is provided on the bypass line 41.

Heaters (not shown) are provided to independently heat the gas lines 12, 14, and 41. As such, the temperatures of the gas lines 12, 14 and 41 can be controlled to avoid condensation of the metal-carbonyl precursor 55 in the gas lines 12, 14, and 41. The temperature of the gas lines 12, 14 and 41 can be controlled from about 20° C. to about 100° C., although in some cases, controlling the temperature from about 25° C. to about 60° C. may be sufficient.

Dilution gases can be supplied from a gas source 19 to the gas line 12 using a gas line 18. The dilution gases can be used to dilute the process gas or to adjust the process gas partial pressure(s). The gas line 18 contains a mass flow controller (MFC) 20 and valves 21. The MFCs 16 and 20, and the valves 17, 21, and 42 are controlled by a controller 40, which controls the supply, shutoff, and the flow of a carrier gas, the metal-carbonyl precursor gas, and a dilution gas. The sensor 45 is also connected to the controller 40 and, based on output of the sensor 45, the controller 40 can control the carrier gas flow through the mass flow controller 16 to obtain the desired metal-carbonyl precursor flow to the process chamber 1.

An exhaust line 24 connects the exhaust chamber 23 to a vacuum pumping system 400. The vacuum pumping system 400 comprises an automatic pressure controller (APC) 59, a trap 57, and a vacuum pump 25. The vacuum pump 25 is used to evacuate the process chamber 1 to a desired degree of vacuum and to remove gaseous species from the process chamber 1 during processing. The APC 59 and the trap 57 can be used in series with the vacuum pump 25. The vacuum pump 25 may comprise a turbo-molecular pump (TMP) capable of pumping speeds up to 5000 liters per second (and greater). Alternately, the vacuum pump 25 may comprise a dry pump.

During processing, the process gas can be introduced into the process chamber 1 and the chamber pressure may be adjusted by the APC 59. The APC 59 can comprise a butterfly-type valve or any suitable valve, such as, for example, a gate valve. The trap 57 can collect unreacted precursor material and by-products from the process chamber 1.

Focusing on the process chamber 1, three substrate lift pins 26 (only two are shown) are provided for holding, raising, and lowering the substrate 50. The substrate lift pins 26 are affixed to a plate 27, and can be lowered to a position below the upper surface of the substrate holder 2. A drive mechanism 28 utilizing, for example, an air cylinder, may be configured to raise and lower the plate 27. The substrate 50 can be transferred into and out of the process chamber 1 through a gate valve 30 and a chamber feed-through passage 29 via a robotic transfer system (not shown) and received by the substrate lift pins 26. Once the substrate 50 is received from the transfer system, it can be lowered to the upper surface of the substrate holder 2 by lowering the substrate lift pins 26.

The processing system 100 may be controlled by a processing system controller 500. In particular, the processing system controller 500 comprises a microprocessor, a memory, and a digital I/O port capable of generating control voltages sufficient to communicate and activate inputs of the processing system 100 as well as monitor outputs from the processing system 100. Moreover, the processing system controller 500 may be coupled to, and exchange information with, the process chamber 1, the precursor delivery system 300 that includes the controller 40 and the precursor heater 13a, the vacuum pumping system 400, the power source 6, and the coolant fluid source 10f.

In the vacuum pumping system 400, the processing system controller 500 is coupled to, and exchanges information with, the automatic pressure controller (APC) 59 for controlling the pressure in the process chamber 1. A program stored in the memory is utilized to control the aforementioned components of the processing system 100 according to a stored process recipe. One example of processing system controller 500 is a DELL PRECISION WORKSTATION 610™, available from Dell Corporation, Dallas, Tex.

A processing system for forming Ru and Re metal layers can comprise a single wafer process chamber 1 as is schematically shown and described in FIG. 1. Alternately, the processing system can comprise a batch type process chamber capable of processing multiple substrates (wafers) 50 simultaneously. In addition to semiconductor substrates 50, (e.g., Si wafers), the substrates can, for example, comprise LCD substrates, glass substrates, or compound semiconductor substrates. The process chamber 1 can, for example, process substrates of any size, such as 200 mm substrates, 300 mm substrates, or even larger substrates. It will be apparent to those skilled in the art that modifications may be made to the processing system 100 chosen for illustration in FIG. 1 without departing from the spirit and scope of the present invention.

Thermal decomposition of the metal-carbonyl precursor 55 and subsequent metal deposition on the substrate 50, is thought to proceed predominantly by CO elimination and desorption of CO by-products from the substrate 50. Incorporation of CO by-products into the metal layer can result from incomplete decomposition of the metal-carbonyl precursor 55, incomplete removal of CO by-products from the metal layer, and re-adsorption of CO by-products from the processing zone 60 onto the metal layer. Lowering of the process chamber pressure results in a shorter residence of gaseous species (e.g., metal-carbonyl precursor, reaction by-products, carrier gas, and dilution gas) in the processing zone 60 above the substrate 50, which in turn, can result in lower CO impurity levels in the metal layer deposited on the substrate 50.

Embodiments of the invention are well suited for depositing thin Ru metal layers on un-patterned substrates and on patterned substrates containing vias (holes), trenches, and other structures. In situations where conformal thin Ru metal layer deposition is required over high aspect ratio structures, the TCVD process described in embodiments of the invention can be a preferred method of deposition.

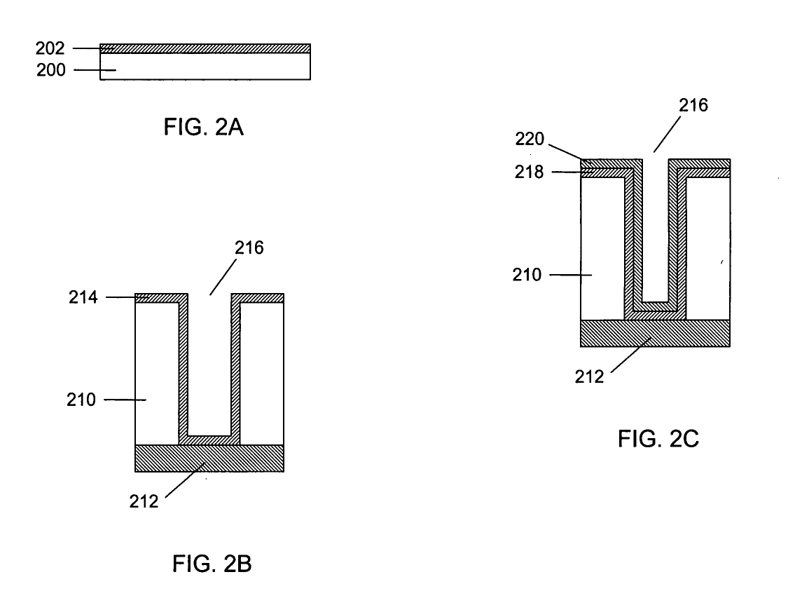

FIG. 2A schematically depicts a substrate 200 containing a thin Ru or Re metal layer 202 deposited thereon, according to an embodiment of the present invention. According to one embodiment, the thickness of the metal layer 202 can be less than about 300 Angstroms (Å). Alternately, the thickness can be less than about 200 Å or even less than about 100 Å.

FIG. 2B schematically shows a patterned substrate 210 containing a thin Ru or Re metal layer 214 deposited thereon according to an embodiment of the present invention. The patterned substrate 210 also contains an opening 216 that can, for example, be a via, a trench, or another structure. The thin Ru or Re metal layer 214 can, for example, be a barrier layer between the patterned substrate 210, the first metal layer 212, and a second metal layer to be deposited in the opening 216. In another example, the thin Ru or Re metal layer 214 can be a seed layer for subsequent deposition of Cu in the opening 216 by a plating process. In yet another example, schematically shown in FIG. 2C, the thin Ru or Re metal layer 220 can be deposited onto a barrier layer 218 containing another material (e.g., W), and subsequently Cu deposited in the opening 216.

It can be difficult to achieve deposition rates that are high enough for device manufacturing when using metal-containing precursor with low vapor pressures. The low vapor pressure can limit the supply of the metal-containing precursor to the processing zone 60 and result in a low deposition rate of a metal-containing layer on the substrate 50. Ru₃(CO)₁₂ and Re₂(CO)₁₀ precursors are examples of metal-carbonyl precursors that have relatively low vapor pressures. For example, the vapor pressure of Ru₃(CO)₁₂ is estimated to be about 0.0055 Torr at 50° C. and about 0.057 Torr at 80° C., and the vapor pressure of Re₂(CO)₁₀ is estimated to be about 0.0034 Torr at 50° C. and about 0.035 Torr at 80° C. For comparison, the vapor pressure of the well known W(CO)₆ precursor is about 0.33 Torr at 50° C. and about 3.5 Torr at 80° C.

In addition to the relatively low vapor pressures of the Ru₃(CO)₁₂ and Re₂(CO)₁₀ precursors, precursor decomposition at moderate temperatures can seriously limit how much the temperature of the precursor container 13 can be raised in order to increase the vapor pressure and supply of the precursor 55 to the processing zone 60.

According to an embodiment of the present invention, a carrier gas is used to enhance the delivery of a metal-carbonyl precursor to the processing zone 60. The use of a relatively low carrier gas flow results in the process gas having a relatively high precursor concentration while permitting a low process chamber pressure. In contrast, a relatively high carrier gas flow results in the process gas having relatively low precursor concentration due to the low vapor pressure and limited evaporation rate of the solid precursor in the precursor container. Furthermore, the use of a relatively high carrier gas flow results in high process chamber pressure due to finite pumping speed of the vacuum pumping system 400 configured for evacuating the process gas from the process chamber 1.

Particulate contamination on substrates is a leading cause for low yields of logic and memory devices. As integrated circuit feature sizes decrease, submicron size particles will have a greater effect on the yield. During processing of the substrate 50, particles can be carried into the process chamber 1 with the incoming process gas, and they may also be generated from chemical reactions that occur during processing of the substrate 50. In general, higher deposition rates can be obtained by increasing the carrier gas flow and the process chamber pressure. However, particle generation has been found to increase at the higher pressures. The current inventors have realized that the use of a relatively low carrier gas flow, reduces the transport of particulate contamination from the precursor container 13 and the gas line 12 to the process chamber 1, thereby reducing particle contamination on the substrate 50.

According to an embodiment of the present invention, a relatively low carrier gas flow, along with a process chamber pressure of less than about 20 mTorr, can provide a relatively high metal deposition rate (8 Å/min, or greater), low particulate contamination, and good step coverage on semiconductor substrates. Alternately, the process chamber pressure can be less that about 10 mTorr.

As will be appreciated by those skilled in the art, the relationship between carrier gas flow rate, process gas flow rate, and process chamber pressure, depends on the volume and geometry of the process chamber 1 and the pumping speed of the vacuum pumping system 400. Furthermore, the design and the temperature of the precursor container 13 affects the evaporation rate of the precursor 55 and the supply of the precursor 55 to the processing zone 60. Therefore, carrier gas flow rates may be different for processing systems configured differently than the exemplary processing system 100 shown in FIG. 1. In addition, minimizing the distance from the precursor container 13 to the processing zone 60 and maximizing the conductance of the gas line 12 can increase the supply of the precursor 55 to the processing zone 60.

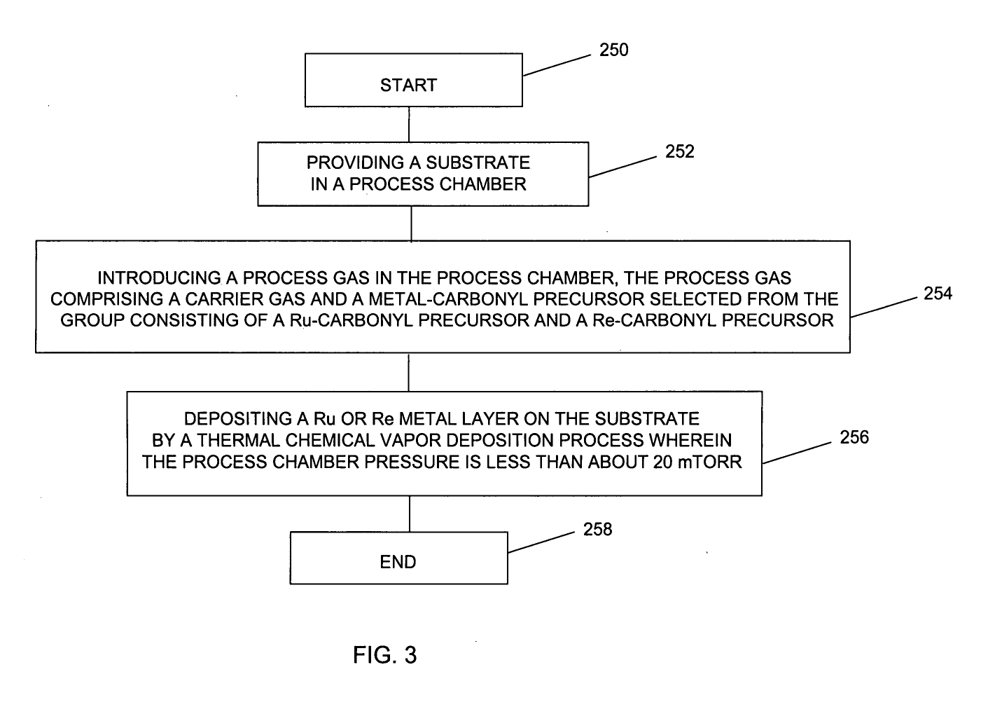

FIG. 3 depicts a flowchart for a process of depositing a metal layer, in accordance with an embodiment of the invention. In task 250, the process is started. In task 252, a substrate is provided in a process chamber.

In task 254, a process gas is introduced in the process chamber, where the process gas includes a carrier gas and a metal-carbonyl precursor selected from the group consisting of a ruthenium-carbonyl precursor and a rhenium-carbonyl precursor. In one embodiment of the invention, the ruthenium-containing precursor can contain Ru₃(CO)₁₂ and the rhenium-containing precursor can contain Re₂(CO)₁₀.

In task 256, a metal layer containing Ru or Re metal is deposited on the substrate by a thermal chemical vapor deposition process where the process chamber pressure is less than about 20 mTorr. Alternately, the process chamber pressure can be less than about 10 mTorr.

According to one embodiment of the present invention, the metal layer thickness can be less than about 300 Å. In other embodiments, the metal layer thickness can be less than 200 Å and, in some cases, the metal layer thickness can be less than about 100 Å.

Moreover, in accordance with one embodiment of the present invention, the metal layer can be deposited at a rate greater than about 5 Å/min. In other embodiments, the metal layer can be deposited at a rate greater than about 10 Å/min, and, in some cases, the deposition rates can be greater than about 40 Å/min.

As indicated in FIG. 3, after the deposition of the meal layer containing Ru or Re, the process terminates in task 258.

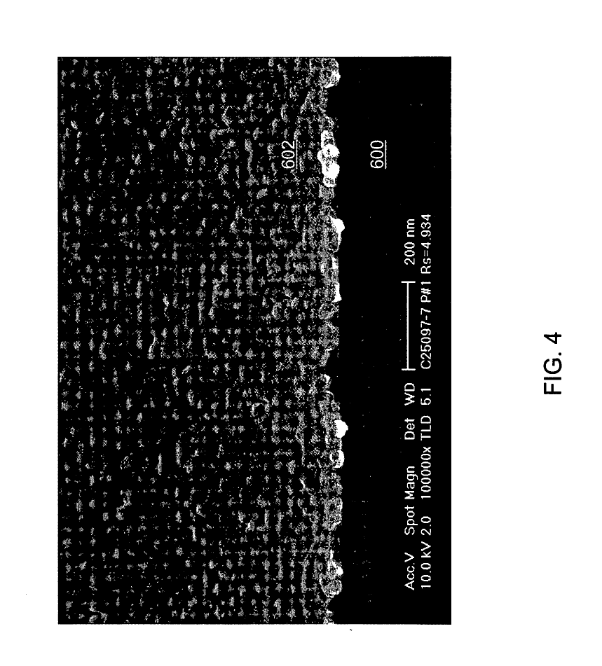

The process parameter space for the TCVD process utilizes a process chamber pressure less than about 20 mTorr, a carrier gas flow rate between about 50 standard cubic centimeters per minute (sccm) and about 400 sccm. Alternately, the carrier gas flow rate can be between about 100 sccm and about 300 sccm, and can be about 150 sccm. Alternately, the process chamber pressure can be less than about 10 mTorr. The dilution gas flow rate can be between about 5 sccm and about 100 sccm. Alternately, the dilution gas flow rate can be between about 10 sccm and about 50 sccm. The carrier gas and the dilution gas can contain an inert gas. The inert gas can contain Ar, He, Ne, Kr, Xe, or N₂, or a combination of two or more thereof. The substrate temperature can be between about 300° C. and about 600° C. Alternately, the substrate temperature can be between about 400° C. and about 500° C. FIG. 4 illustrates a cross-sectional SEM micrograph of a Ru metal layer deposited by a low-pressure thermal chemical vapor deposition process, in accordance with an embodiment of the present invention. The Ru layer 602 was deposited onto the Si substrate 600 using a Ru₃(CO)₁₂ precursor, a process chamber pressure of about 7.9 mTorr, a substrate temperature of 400° C., and a precursor container temperature of 63° C. The Ar carrier gas flow was 150 sccm and the dilution gas flow was 20 sccm. The Ru deposition rate was about 8 Å/min and the electrical resistivity of the approximately 250 Å thick Ru layer 402 was about 12.4 μohm-cm. This electrical resistivity value, when compared to the bulk resistivity of 7.1 μohm-cm, is reasonable for integration of Ru metal layers into semiconductor devices.

The 250 Å thick Ru metal layer 302 shown in FIG. 3 evidenced larger grains than Ru metal layers deposited at higher process chamber pressures, for example at 200 mTorr. However, thinner Ru metal layers (thicknesses less than about 100 Å) that were deposited at process chamber pressures less than about 10 mTorr showed smaller grains than Ru metal layers deposited at process chamber pressures of 200 mTorr. In addition, fewer particles were observed on Ru metal layers deposited at process chamber pressures less that than about 10 mTorr than were observed on Ru metal layers deposited at higher process chamber pressures.

In another embodiment of the present invention, a Ru metal layer was deposited onto a patterned Si substrate. The patterned Si substrate contained via holes with an aspect ratio of about 4.4 (width of about 0.21 μm, and depth of about 0.92 μm). The Ru metal layer was deposited using the same process conditions as described above but using a precursor container temperature of 65° C. SEM micrographs indicated a step coverage of about 44 percent (%). Step coverage refers to the Ru layer thickness on the via sidewall near the bottom of the via relative to the Ru layer thickness away from the via.

For comparison, a Ru metal layer was deposited onto the patterned Si substrate using a process chamber pressure of about 200 mTorr, a carrier gas flow rate of 880 sccm, a substrate temperature of 400° C., and a precursor container temperature of 65° C. The resulting step coverage of the Ru metal layer was only about 7.5%, compared to the step coverage of about 44% for a process chamber pressure of 7.9 mTorr.

It should be understood that various modifications and variations of the present invention may be employed in practicing the invention. It is, therefore, to be understood that, within the scope of the appended claims, the invention may be practiced otherwise than as specifically described herein.

What is claimed is:

1. A method of depositing a metal layer on a substrate, comprising:
providing a substrate in a process chamber;
introducing a process gas in the process chamber, the process gas comprising a carrier gas and metal-carbonyl precursor selected from the group consisting of a ruthenium-carbonyl precursor and a rhenium-carbonyl precursor; and
depositing a Ru or Re metal layer on the substrate by a thermal chemical vapor deposition process, wherein a process chamber pressure is less than about 20 mTorr.

2. The method according to claim 1, wherein the process chamber pressure is less than about 10 mTorr.

3. The method according to claim 1, wherein the ruthenium-carbonyl precursor comprises Ru₃(CO)₁₂.

4. A method according to claim 1, wherein the rhenium-carbonyl precursor comprises Re₂(CO)₁₀.

5. The method according to claim 1, wherein a carrier gas flow is between about 50 sccm and about 400 sccm.

6. The method according to claim 1, wherein a carrier gas flow is between about 100 sccm and about 300 sccm.

7. The method according to claim 1, wherein the carrier gas comprises Ar, He, Ne, Kr, Xe, or N₂, or a combination of two or more thereof.

8. The method according to claim 1, wherein the process gas further comprises a dilution gas.

9. The method according to claim 8, wherein a flow of the dilution gas is between about 5 sccm and about 100 sccm.

10. The method according to claim 8, wherein a flow of the dilution gas is between about 10 sccm and about 50 sccm.

11. The method according to claim 8, wherein the dilution gas comprises Ar, He, Ne, Kr, Xe, or N₂, or a combination of two or more thereof.

12. The method according to claim 1, wherein a temperature of the substrate is between about 300° C. and about 600° C.

13. The method according to claim 1, wherein a temperature of the substrate is between about 400° C. and about 500° C.

14. The method according to claim 1, wherein the substrate comprises a semiconductor substrate, an LCD substrate, or a glass substrate, or a combination of two or more thereof.

15. The method according to claim 1, wherein a thickness of the metal layer is less than about 300 Å.

16. The method according to claim 1, wherein a thickness of the metal layer is less than about 200 Å.

17. The method according to claim 1, wherein a thickness of the metal layer is less than about 100 Å.

18. The method according to claim 1, wherein the metal layer is deposited at a rate greater than about 5 Å/min.

19. The method according to claim 1, wherein the metal layer is deposited at a rate greater than about 10 Å/min.

20. A method of depositing a metal layer on a patterned substrate, comprising:
providing a patterned substrate in a process chamber, the patterned substrate containing one or more vias, trenches, or combinations thereof;
introducing a process gas in the process chamber, the process gas comprising a metal precursor selected from the group consisting of a ruthenium-carbonyl precursor and a rhenium-carbonyl precursor; and
depositing a Ru or Re metal layer on the patterned substrate by a thermal chemical vapor deposition process, wherein process chamber pressure is less than about 20 mTorr.

21. The method according to claim 20, wherein the process chamber pressure is less than about 10 mTorr.

22. The method according to claim 20, wherein the ruthenium-carbonyl precursor comprises Ru₃(CO)₁₂.

23. The method according to claim 20 wherein the rhenium-carbonyl precursor comprises Re₂(CO)₁₀.

24. The method according to claim 20, wherein the process gas flow is between about 50 sccm and about 400 sccm.

25. The method according to claim 20, wherein the process gas flow is between about 100 sccm and about 300 sccm.

26. The method according to claim 20, wherein the process gas further comprises a carrier gas comprising Ar, He, Ne, Kr, Xe, or N₂, or a combination of two or more thereof.

27. The method according to claim 20, wherein the process gas further comprises a dilution gas.

28. The method according to claim 27, wherein dilution gas flow is between about 5 sccm and about 100 sccm.

29. The method according to claim 27, wherein the dilution gas flow is between about 10 sccm and about 50 sccm.

30. The method according to claim 27, wherein the dilution gas comprises Ar, He, Ne, Kr, Xe, or N₂, or a combination of two or more thereof.

31. The method according to claim 20, wherein a temperature of the substrate is between about 300° C. and about 600° C.

32. The method according to claim 20, wherein a temperature of the substrate is between about 400° C. and about 500° C.

33. The method according to claim 20, wherein the substrate comprises a semiconductor substrate, a LCD substrate, or a glass substrate, or a combination of two or more thereof.

34. The method according to claim 20, wherein a thickness of the metal layer is less than about 300 Å.

35. The method according to claim 20, wherein a thickness of the metal layer is less than about 200 Å.

36. The method according to claim 20, wherein a thickness of the metal layer is less than about 100 Å.

37. The method according to claim 20, wherein the metal layer is deposited at a rate greater than about 5 Å/min.

38. The method according to claim 20, wherein the metal layer is deposited at a rate greater than about 10 Å/min.
